(19) United States
(12) Patent Application Publication
(10) Pub. No.: US 2013/0082229 A1
(43) Pub. Date: Apr. 4, 2013

(54) MIXED IONIC-ELECTRONIC CONDUCTION MEMORY CELL

(71) Applicant: Frederick T. Chen, Hsinchu County (TW)

(72) Inventor: Frederick T. Chen, Hsinchu County (TW)

(73) Assignee: INDUSTRIAL TECHNOLOGY RESEARCH INSTITUTE, Hsinchu (TW)

(21) Appl. No.: 13/414,727

(22) Filed: Mar. 8, 2012

Related U.S. Application Data
(60) Provisional application No. 61/541,092, filed on Sep. 30, 2011.

(51) Int. Cl. H01L 47/00

(52) U.S. Cl. 257/4; 257/E47.001

(57) ABSTRACT

A mixed ionic-electronic conduction (MIEC) memory cell including a mixed ionic-electronic conductor containing dopants therein, a heater disposed adjacent to the mixed ionic-electronic conductor, a pair of first electrodes electrically connected to the mixed ionic-electronic conductor, and at least one pair of second electrodes electrically connected to the mixed ionic-electronic conductor is provided. The pair of first electrodes drive the dopants in the mixed ionic-electronic conductor to drift along a first direction when the mixed ionic-electronic conductor is heated by the heater. The pair of second electrodes locally modify a distribution of the dopants along a second direction when the mixed ionic-electronic conductor is heated by the heater, and the first direction is different from the second direction.

### CROSS-REFERENCE TO RELATED APPLICATION

This application claims the priority benefit of U.S. Provisional Application Ser. No. 61/541,092, filed Sep. 30, 2011. The entirety of the above-mentioned patent application is hereby incorporated by reference herein and made a part of this specification.

### BACKGROUND OF THE DISCLOSURE

1. Field of the Disclosure

The present disclosure relates to a memory cell. More particularly, the present disclosure relates to a mixed ionic-electronic conduction (MIEC) memory cell.

2. Description of Related Art

The ability to transport both ionic and electronic species is one of the most important properties of a mixed ionic-electronic conductor. Generally, the mixed ionic-electronic conductor conducts electrons, holes, and ions and contains immobile defects (i.e. charged defects). In the mixed ionic-electronic conductor, ions are generally mobile at an elevated temperature when an electric field is applied to the mixed ionic-electronic conductor. For instance, Li⁺ cations in a poly-silicon (1000 Ω-cm) are mobile at 450° C. when an electric field is applied to the mixed ionic-electronic conductor. In the mixed ionic-electronic conductor, positively charged defects or ions act as n-type dopants while negatively charged defects or ions act as p-type dopants.

When an electric field is applied a pair of access electrodes, ions in the mixed ionic-electronic conductor at an elevated temperature are driven to drift along the direction of the electric field and dopants distribution in the mixed ionic-electronic conductor is changed accordingly. Since the dopants distribution is changed, a p-n junction is generated within the mixed ionic-electronic conductor. In other words, data can be recorded or stored as a programmable p-n junction resistance. When the temperature is lower, the dopants distribution in the mixed ionic-electronic conductor is frozen and can be read by the pair of access electrodes.

When the mixed ionic-electronic conductor serves as a storage medium of memory cells, storage density is an important issue required to be considered.

### SUMMARY

The present disclosure provides a mixed ionic-electronic conduction (MIEC) memory cell having at least two pairs of first electrodes for driving drive the dopants in the mixed ionic-electronic conductor to drift along different directions.

The present disclosure provides a mixed ionic-electronic conduction (MIEC) memory cell including a mixed ionic-electronic conductor containing dopants therein, a heater disposed adjacent to the mixed ionic-electronic conductor, a pair of first electrodes electrically connected to the mixed ionic-electronic conductor, and at least one pair of second electrodes electrically connected to the mixed ionic-electronic conductor. The pair of first electrodes drive the dopants in the mixed ionic-electronic conductor to drift along a first direction when the mixed ionic-electronic conductor is heated by the heater. The pair of second electrodes locally modify a distribution of the dopants along a second direction when the mixed ionic-electronic conductor is heated by the heater, and the first direction is different from the second direction.

In order to the make the aforementioned and other features and advantages of the present disclosure comprehensible, several embodiments accompanied with figures are described in detail below.

### BRIEF DESCRIPTION OF THE DRAWINGS

The accompanying drawings constituting a part of this specification are incorporated herein to provide a further understanding of the disclosure. Here, the drawings illustrate embodiments of the disclosure and, together with the description, serve to explain the principles of the disclosure.

FIG. 1A is a cross-sectional view a MIEC memory cell according to the first embodiment of the present disclosure.

FIG. 1B schematically illustrates the MIEC memory cell according to the first embodiment of the present disclosure.

FIG. 1C is a top view of the MIEC memory cell according to the first embodiment of the present disclosure.

FIG. 2A is a cross-sectional view a MIEC memory cell according to the second embodiment of the present disclosure.

FIG. 2B schematically illustrates the MIEC memory cell according to the second embodiment of the present disclosure.

FIG. 2C is a top view of the MIEC memory cell according to the second embodiment of the present disclosure.

FIG. 3A is a cross-sectional view a MIEC memory cell according to the third embodiment of the present disclosure.

FIG. 3B schematically illustrates the MIEC memory cell according to the third embodiment of the present disclosure.

FIG. 4A is a cross-sectional view a MIEC memory cell according to the fourth embodiment of the present disclosure.

FIG. 4B schematically illustrates the MIEC memory cell according to the fourth embodiment of the present disclosure.

### DESCRIPTION OF EMBODIMENTS

### First Embodiment

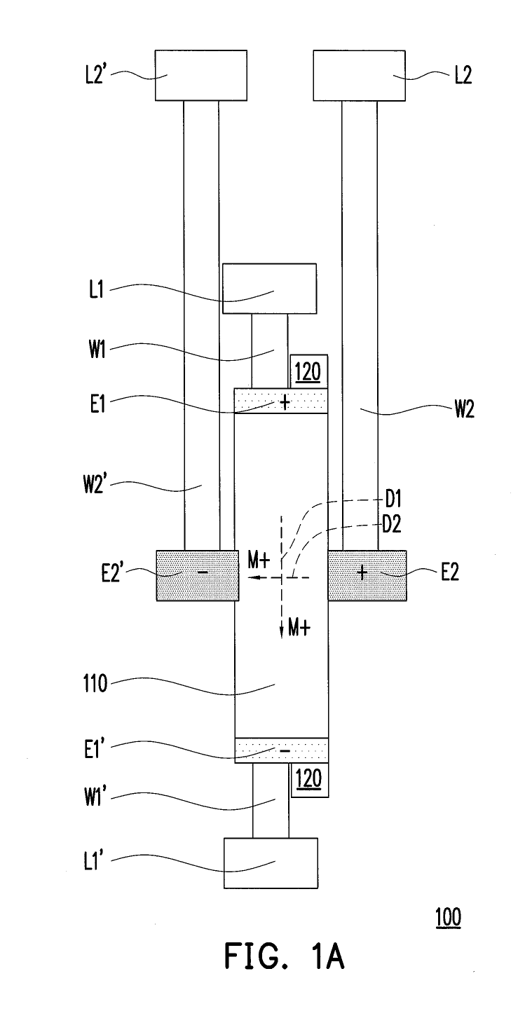

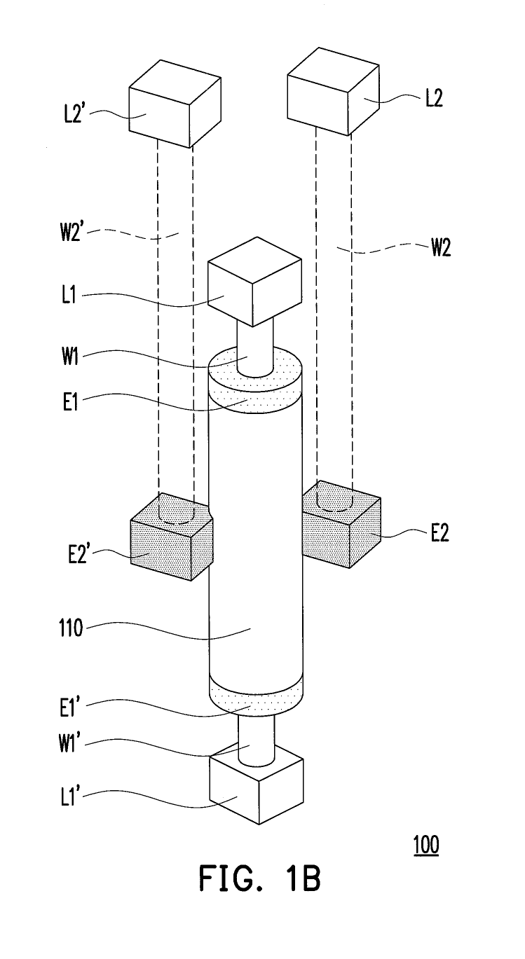

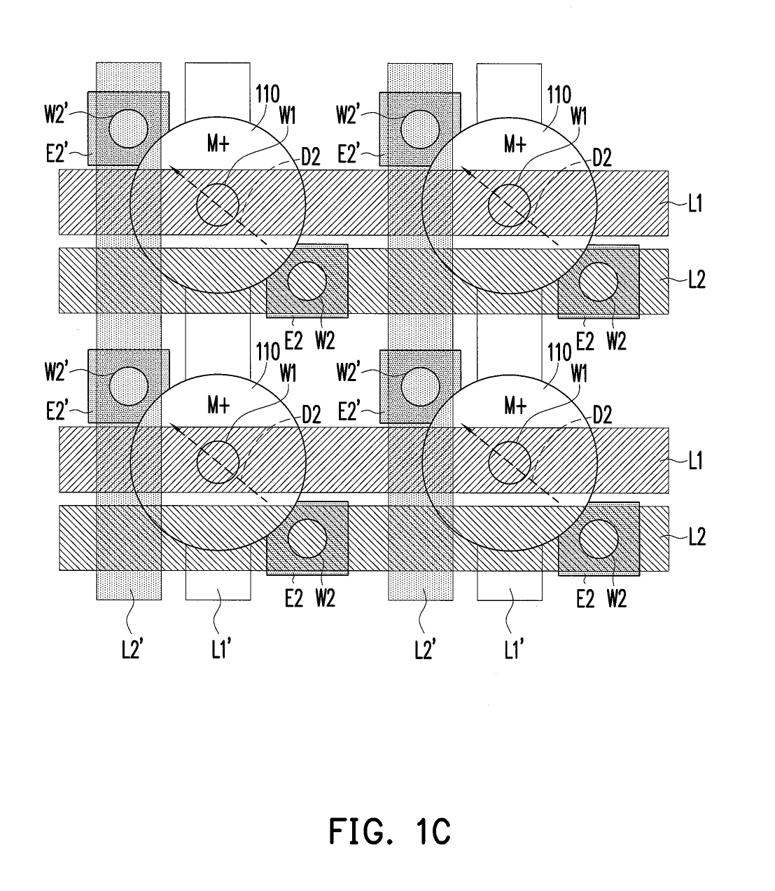

FIG. 1A is a cross-sectional view a MIEC memory cell according to the first embodiment of the present disclosure, FIG. 1B schematically illustrates the MIEC memory cell according to the first embodiment of the present disclosure, and FIG. 1C is a top view of the MIEC memory cell according to the first embodiment of the present disclosure. Referring to FIG. 1A through FIG. 1C, the MIEC memory cell 100 of this embodiment includes a mixed ionic-electronic conductor 110 containing dopants M+ therein, a heater 120 disposed adjacent to the mixed ionic-electronic conductor 110, a pair of first electrodes E1, E1′ electrically connected to the mixed ionic-electronic conductor 110, and at least one pair of second electrodes E2, E2′ electrically connected to the mixed ionic-electronic conductor 110 is provided. The pair of first electrodes E1, E1′ drive the dopants M+ in the mixed ionic-electronic conductor 110 to drift along a first direction D1 when the mixed ionic-electronic conductor 110 is heated by the heater 120. The pair of second electrodes E2, E2′ locally modify a distribution of the dopants M+ along a second direction D2 when the mixed ionic-electronic conductor 110 is heated by the heater 120, and the first direction D1 is different from the second direction D2. For example, the first direction D1 is perpendicular to the second direction D2.

In this embodiment, the MIEC memory cell 100 may further include a pair of crossed first access lines L1, L1′ electrically connected to the pair of first electrodes E1, E1′; and at least one pair of crossed second access lines L2, L2′ electrically connected to the at least one pair of second electrodes E2, E2′.

In this embodiment, the mixed ionic-electronic conductor 110 may be a semiconductor containing positively charged defects or ions acting as n-type dopants or may be a semiconductor containing negatively charged defects or ions acting as p-type dopants. For example, the material of the mixed ionic-electronic conductor 110 includes doped silicon, ytrria-stabilized zirconia (YSZ), doped SrTiO₃, CuOx, CeOx or NiO.

When a data-recording procedure is performed, the mixed ionic-electronic conductor 110 is heated to an elevated temperature by the heater 120 and the dopants M+ are mobile at the elevated temperature. In this embodiment, the heater 120 is, for example, fabricated as a titanium nitride or titanium silicon nitride contact plug. The elevated temperature about 400° C. to 600° C. can be achieved by the heater 120, for instance. During the data-recording procedure, the distribution of dopants M+ in the mixed ionic-electronic conductor 110 is firstly changed by an electric field provided by the pair of first electrodes E1, E1′, and then is locally modified by another electric field provided by the pair of second electrodes E2, E2′. As shown in FIG. 1A, the pair of first electrodes E1, E1′ drive the dopants M+ in the mixed ionic-electronic conductor 110 to drift vertically and the pair of second electrodes E2, E2′ drive the dopants M+ in the mixed ionic-electronic conductor 110 to drift laterally. Specifically, p-n junction is generated within the mixed ionic-electronic conductor and data can be recorded or stored as a programmable p-n junction resistance.

When a data-reading procedure is performed, the temperature of the mixed ionic-electronic conductor 110 is lowered and the dopants M+ are immobile. During the data-reading procedure, the distribution of dopants M+ in the mixed ionic-electronic conductor 110 is frozen and cannot be changed because the temperature of the mixed ionic-electronic conductor 110 is lowered and the dopants M+ in the mixed ionic-electronic conductor 110 are immobile.

When a data-erasing procedure is performed, the mixed ionic-electronic conductor 110 is heated again to the aforesaid elevated temperature by the heater 120 and the dopants M+ are mobile at the elevated temperature. During the data-erasing procedure, the distribution of dopants M+ in the mixed ionic-electronic conductor 110 can be changed by the electric field provided by the pair of second electrodes E2, E2′. If data at a different location is required to be changed, the electric field provided by the pair of first electrodes E1, E1′ may be used to move the dopant distribution so that a different vertical location can be altered by E2, E2′. After the data-erasing procedure is performed, the distribution of dopants M+ in the mixed ionic-electronic conductor 110 can be recovered or can be further changed.

As shown in FIG. 1A, the heater 120 is disposed on and in contact with the pair of first electrodes E1′ E1′. In an alternative embodiment, the heater 120 may be installed in the pair of first electrodes E1, E1′. In another alternative embodiment, the heater 120 may be disposed around and in contact with the mixed ionic-electronic conductor 110 such that the mixed ionic-electronic conductor 110 can be heated by the heater 120 more efficiently.

The pair of first electrodes E1, E1′ and the pair of second electrodes E2, E2′ are impenetrable to the dopants M+ in the mixed ionic-electronic conductor 110.

As shown in FIG. 1C, the MIEC memory cell 100 of this embodiment can be arranged in an array. It is noted that reverse-bias can be applied to unselected cells and the unselected cells can serve as isolation between selected cells. The unselected MIEC memory cell would avoid leakage current.

### Second Embodiment

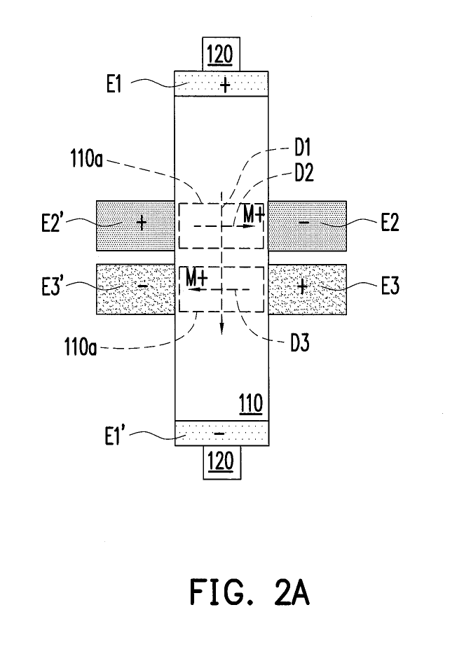

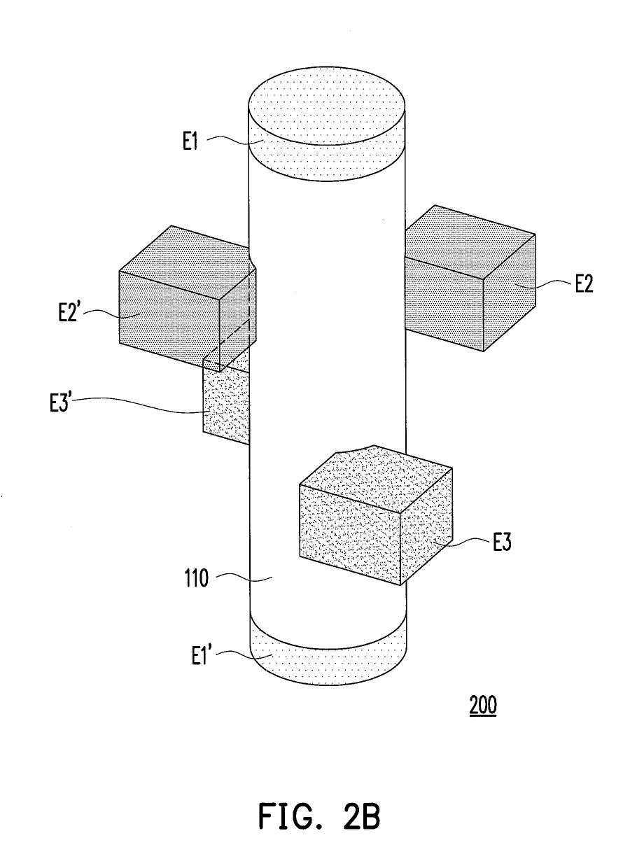

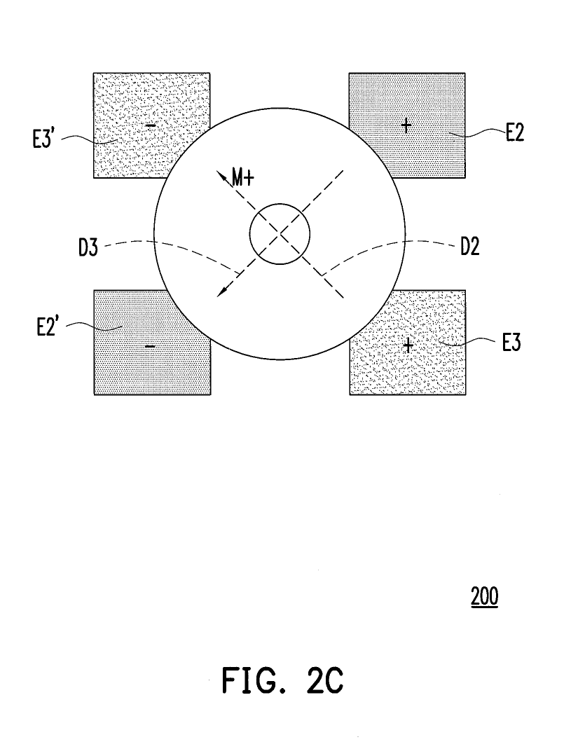

FIG. 2A is a cross-sectional view a MIEC memory cell according to the second embodiment of the present disclosure, FIG. 2B schematically illustrates the MIEC memory cell according to the second embodiment of the present disclosure, and FIG. 2C is a top view of the MIEC memory cell according to the second embodiment of the present disclosure. Referring to FIG. 2A through FIG. 2C, the MIEC memory cell 200 of this embodiment is similar with the MIEC memory cell 100 of the first embodiment except that MIEC memory cell 200 includes a plurality of pairs of lateral electrodes E2, E2′, E3, E3′ and a plurality of programmable bit regions are generated in the mixed ionic-electronic conductor 110. In this embodiment, two pairs of lateral electrodes E2, E2′, E3, E3′ and two programmable bit regions 110a are described for illustration. However, more than two pairs of lateral electrodes can be used in the MIEC memory cell 200. The quantity and dimension of the second electrodes and programmable bit regions are not limited in this disclosure.

In FIG. 2A and FIG. 2C, during the data-recording procedure, the distribution of dopants M+ in the mixed ionic-electronic conductor 110 is firstly changed by an electric field provided by the pair of first electrodes E1, E1′, and then is locally modified in a different direction by another electric field provided by the pair of lateral electrodes E2, E2′ and the pair of lateral electrodes E3, E3′. As shown in FIG. 2A and FIG. 2C, the pair of second electrodes E2, E2′ and the pair of second electrodes E3, E3′ respectively drive the dopants M+ in the mixed ionic-electronic conductor 110 to drift laterally. Specifically, the pair of lateral electrodes E2, E2′ drive the dopants M+ in the mixed ionic-electronic conductor 110 to drift along a direction D2 while the pair of lateral electrodes E3, E3′ drive the dopants M+ in the mixed ionic-electronic conductor 110 to drift along a direction D3.

### Third Embodiment

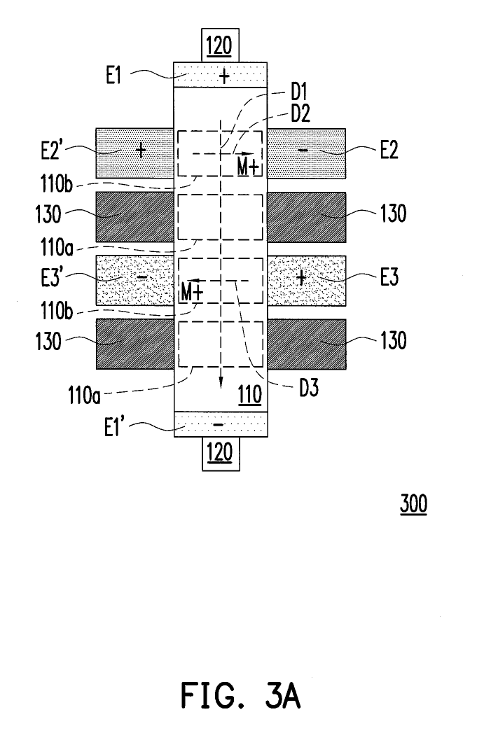

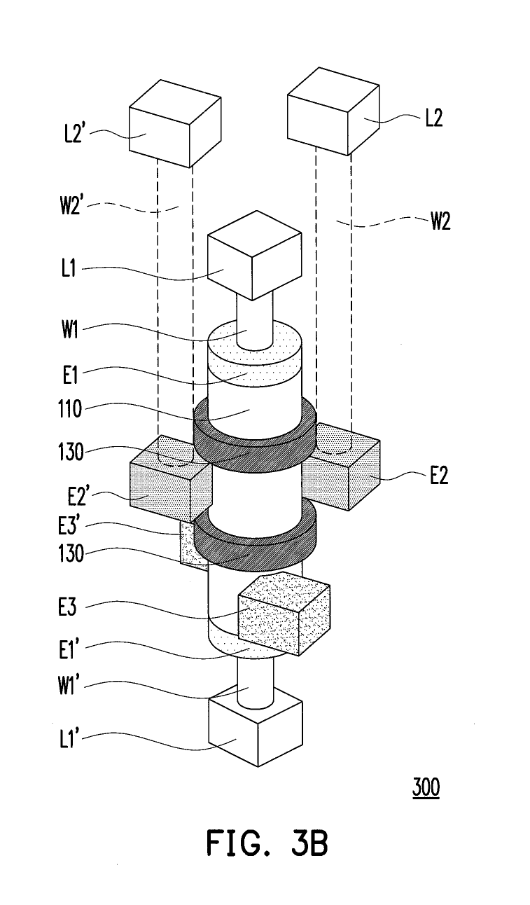

FIG. 3A is a cross-sectional view a MIEC memory cell according to the third embodiment of the present disclosure, and FIG. 3B schematically illustrates the MIEC memory cell according to the third embodiment of the present disclosure. Referring to FIG. 3A and FIG. 3B, the MIEC memory cell 300 of this embodiment is similar with the MIEC memory cell 200 of the second embodiment except that MIEC memory cell 300 further includes at least one surrounding shield 130.

In this embodiment, two surrounding shields 130 are described for illustration. Each of the surrounding shields 130 surrounds parts of the mixed ionic-electronic conductor 110 and is electrically floated. In other words, the outer surface of mixed ionic-electronic conductor 110 is partially covered by the surrounding shields 130. Specifically, programmable bit regions 110a are separated by the shielding regions 110b generated in the mixed ionic-electronic conductor 110.

It is noted that the dimension and the quantity of the surrounding shields 130 are not limited in this embodiment. For example, if one ordinary skilled in the art want to separate two programmable bit regions 110a, only one surrounding shield 130 is required.

During the data-recording procedure, only few current goes into the shielding regions 110b because the electric field in the shielding regions 110b is almost zero. In other words, the shielding regions 110b can be considered as low electric field regions. Since the dopants M+ do slow down in the shielding regions 110b, the shielding regions 110b is useful for bit separation.

### Fourth Embodiment

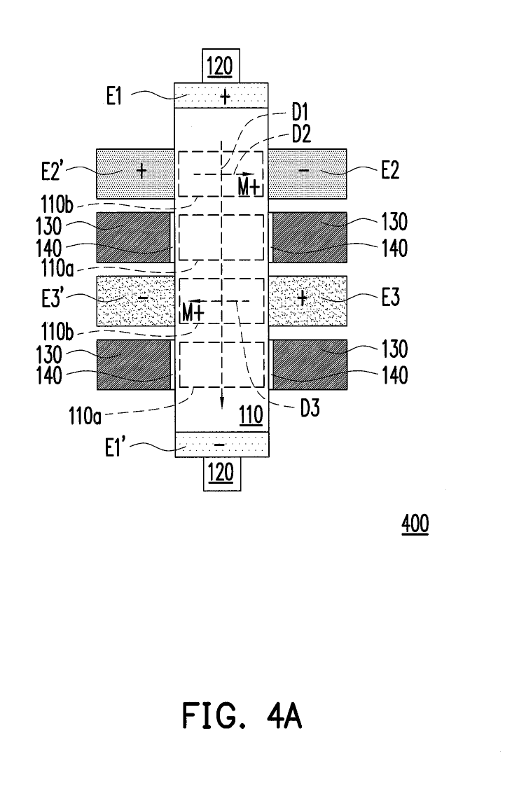

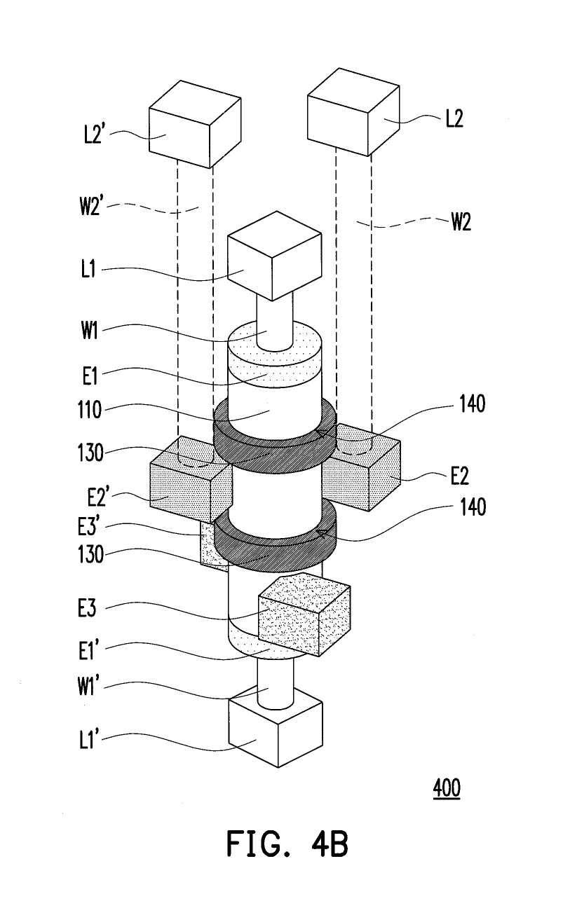

FIG. 4A is a cross-sectional view a MIEC memory cell according to the fourth embodiment of the present disclosure, and FIG. 4B schematically illustrates the MIEC memory cell according to the fourth embodiment of the present disclosure. Referring to FIG. 4A and FIG. 4B, the MIEC memory cell 400 of this embodiment is similar with the MIEC memory cell 300 of the third embodiment except that MIEC memory cell 400 further includes at least one dielectric insulator material 140 between the surrounding shield 130 and the mixed ionic-electronic conductor 110.

In this embodiment, the material of the dielectric insulator material 140 is silicon nitride or silicon dioxide, for example.

In this disclosure, since the MIEC memory cell is capable of storing or recording data at multiple vertical locations, storage density of the MIEC memory cell is large.

Although the present disclosure has been disclosed above by the embodiments, they are not intended to limit the present disclosure. Anyone skilled in the art can make some modifications and alteration without departing from the spirit and scope of the present disclosure. Therefore, the protecting range of the present disclosure falls in the appended claims.

What is claimed is:

1. A mixed ionic-electronic conduction (MIEC) memory cell, comprising:
a mixed ionic-electronic conductor containing dopants therein;
a heater disposed adjacent to the mixed ionic-electronic conductor;
a pair of first electrodes electrically connected to the mixed ionic-electronic conductor, the pair of first electrodes driving the dopants in the mixed ionic-electronic conductor to drift along a first direction when the mixed ionic-electronic conductor is heated by the heater; and
at least one pair of lateral electrodes electrically connected to the mixed ionic-electronic conductor, each pair of lateral electrodes locally modifying a distribution of the dopants along a direction different from the first direction when the mixed ionic-electronic conductor is heated by the heater.

2. The MIEC memory cell of claim 1, wherein the mixed ionic-electronic conductor comprises a semiconductor containing positively charged defects or ions acting as n-type dopants.

3. The MIEC memory cell of claim 1, wherein the mixed ionic-electronic conductor comprises a semiconductor containing negatively charged defects or ions acting as p-type dopants.

4. The MIEC memory cell of claim 1, wherein the mixed ionic-electronic conductor is heated to an elevated temperature by the heater and the dopants are mobile at the elevated temperature when a data-recording procedure is performed.

5. The MIEC memory cell of claim 1, wherein the heater is disposed on and in contact with the pair of first electrodes.

6. The MIEC memory cell of claim 1, wherein the heater is installed in the pair of first electrodes.

7. The MIEC memory cell of claim 1, wherein each pair of lateral electrodes locally modifies a distribution of dopants in its own unique direction perpendicular to the second direction.

8. The MIEC memory cell of claim 7, wherein the pair of first electrodes drive the dopants in the mixed ionic-electronic conductor to drift vertically and each pair of lateral electrodes drives the dopants in the mixed ionic-electronic conductor to drift laterally.

9. The MIEC memory cell of claim 1, wherein the pair of first electrodes and the pair of second electrodes are impenetrable to the dopants in the mixed ionic-electronic conductor.

10. The MIEC memory cell of claim 1, further comprising:
a pair of crossed first access lines, electrically connected to the pair of first electrodes; and
at least one pair of crossed second access lines, electrically connected to the at least one pair of lateral electrodes.

11. The MIEC memory cell of claim 1, wherein the at least one pair of lateral electrodes comprises N pairs of lateral electrodes, and N is an integer greater than 1.

12. The MIEC memory cell of claim 11, further comprising at least one surrounding shield, wherein each surrounding shield surrounds the mixed ionic-electronic conductor and is located vertically between two pairs of lateral electrodes.

13. The MIEC memory cell of claim 12, further comprising at least one dielectric insulator material between at least one surrounding shield and the mixed ionic-electronic conductor.

14. The MIEC memory cell of claim 12, wherein at least one surrounding shield is electrically floated.
